(19) United States
(12) Patent Application Publication
(10) Pub. No.: US 2023/0280407 A1
(43) Pub. Date: Sep. 7, 2023

(54) Verfahren zur Diagnose einer Gerätebatterie eines technischen Geräts auf Basis elektrochemischer Modellparameter

(71) Applicant: Robert Bosch GmbH, Stuttgart (DE)

(72) Inventors: Christoph Woll, Gerlingen (DE); Christoph Kroener, Freiberg Am Neckar (DE)

(21) Appl. No.: 18/177,241

(22) Filed: Mar. 2, 2023

(30) Foreign Application Priority Data
Mar. 2, 2022 (DE) 102022202112.6

(51) Int. Cl. G01R 31/367; G01R 31/392; G01R 31/371

(52) U.S. Cl. CPC G01R 31/367; G01R 31/392; G01R 31/371

(57) ABSTRACT

A method for detecting a fault of a device battery or battery cell using a battery model, wherein the battery model is based on a differential equation system and designed to indicate a progression of an operational variable dependent on an internal battery state determined by a model parameter of the battery model. The method includes providing a temporal operational variable progression of multiple operational variables for a period of time. The method includes adjusting the model parameter of the electrochemical battery model based on the operational variable progression over the period of time. The method includes detecting a fault type dependent on a predetermined rule, wherein the rule indicates a fault condition dependent on a deviation of the model parameter from a corresponding predetermined model parameter, and, when the fault condition of the rule is satisfied, signaling the fault type.

### BACKGROUND OF INVENTION

The invention relates to methods for diagnosing device batteries for technical devices, in particular to methods for diagnosing device batteries by anomaly detection.

The supply of energy to network-independently operated electrical devices and machines, such as electrically drivable motor vehicles, as a rule takes place by means of device batteries or vehicle batteries. These batteries supply electrical energy for operating the devices.

Device batteries degrade over their service life, depending on their load or usage. This so-called “ageing” leads to a continuously decreasing maximum power or storage capacity. The ageing state corresponds to a measure for indicating the ageing of energy stores. In accordance with the convention, a new device battery can have a 100% ageing state (regarding its capacity, SOH-C) which increasingly decreases over the course of its service life. A degree of ageing of the device battery (temporal change in the aging state) depends on an individual load on the device battery, i.e., in the case of vehicle batteries of motor vehicles, on the usage behavior of a driver, external ambient conditions and on the type of vehicle battery.

In order to monitor device batteries from a plurality of devices, operational variable data are typically continuously captured and transmitted in block fashion to a central unit external to the device as operational variable progressions. In the case of device batteries having a plurality of battery cells, the operational variables can be captured at the cell level and transmitted to the central unit in compressed form. To evaluate the operational variable data, in particular to determine ageing states in models based on differential equations, the operational variable data is scanned with a comparatively high temporal resolution (scanning frequencies) of, e.g., between 1 and 100 Hz and an ageing state is determined therefrom using a time integration method.

To evaluate the operational variable data, in particular to determine ageing conditions, an electrochemical battery model is used, which is based on a differential equation system with a plurality of non-linear differential equations. The operational variable data enables battery states to be modeled using a time integration method. Such electrochemical battery models are known, for example, from the publications US 2016/023,566, US 2016/023,567 and US 2020/150,185.

The conduction in the central unit enables the use and adjustment of the electrochemical battery model for a plurality of device batteries having similar battery cells or cell chemistry. The calculation of the battery states using a differential equation system is computationally consuming, so the computational load on the in-device computing means can be reduced by shifting it to the central unit.

In battery-powered technical devices, the proper functioning of the device battery used must be regularly monitored for faults for safety reasons, especially at high energy densities. If a battery cell, a unit consisting of multiple battery cells or the entire device battery fails, the technical device can become inoperable, depending on the fault that has occurred and, under some circumstances, the safety of the technical device can be compromised in the event of malfunctions leading to a severe temperature increase.

However, faults in device batteries are not detected until applied fault thresholds for operational variables, e.g., cell voltage, module temperature, current level, charge level, and ageing state level, are exceeded.

### SUMMARY OF THE INVENTION

According to the present invention, there is provided a method for diagnosing a device battery of a technical device having one or more battery cells as well as a device and a battery system.

Further configurations are specified in the dependent claims.

According to a first aspect, a method in particular, an at least partially computer-implemented method, for detecting a fault of a device battery or a battery cell in a technical device using an electrochemical battery model, wherein the battery model is based on a differential equation system for describing an electrochemical and/or physical behavior of the device battery in order to indicate a progression of at least one operational variable dependent on an internal battery state determined by at least one model parameter of the battery model, said method comprising the following steps:
providing a temporal operational variable progression of multiple operational variables for a specific period of time;
adjusting the at least one model parameter of the electrochemical battery model based on the operational variable progression in the specific period of time, in particular by way of fitting methods;
detecting a fault type dependent on at least one predetermined rule associated with the type of fault, wherein the at least one rule indicates at least one fault condition dependent on at least one deviation of the at least one model parameter from a corresponding predetermined model parameter;
when the fault condition of the at least one rule is satisfied, signaling the fault type.

According to one embodiment, the method can be performed in an external central unit communicatively connected to a plurality of device batteries and providing the electrochemical battery model for all device batteries, and in particular for all battery cells of the device batteries, wherein operational variable progressions of all device batteries or battery cells in the central unit are provided, and adjustment of the model parameters based on the operational variable progressions is performed in the central unit.

The internal state of a device battery cannot typically be directly measured. This would require a number of sensors inside the device battery that would make the production of such a device battery cost-intensive, as well as complex, and would increase the space requirement.

Monitoring of device batteries of a plurality of devices is therefore performed in an external central unit for reasons of capacity. For this purpose, the devices transmit temporal operational variable progressions of operational variables of the device batteries to the central unit, wherein a current electrochemical state and/or ageing state is determined in the central unit. Depending on the model used, time series of operational variables are continuously recorded as operational variable progressions, e.g., battery current, battery temperature, state of charge and/or battery voltage, and transmitted to the central unit in block fashion and optionally in compressed form. The operational variable progressions are evaluated in the central unit, so that a device-specific state and, optionally, further variances can be calculated/determined based on one or more ageing state models. The evaluation can be based on the entire device battery, on individual battery cells or units/modules consisting of multiple battery cells.

In the case of device batteries, the ageing state (state of health, SOH) is the key variable to indicate a remaining battery capacity or remaining battery charge. The ageing state represents a measure of the ageing of the device battery. In the case of a device battery or a battery module or a battery cell, the ageing state can be indicated as a capacity retention rate (SOH-C). The capacity maintenance rate SOH-C, i.e., the capacity-related state of ageing, is indicated as the ratio of the measured instantaneous capacity to an initial capacity of the fully charged battery and decreases with ageing. Alternatively, the ageing state can be given as an increase in internal resistance (SOH-R) with respect to internal resistance at the start of the service life of the device battery. The relative change in the internal resistance SOH-R increases with increasing ageing of the battery.

Device batteries typically comprise a plurality of battery cells, which can be monitored separately. This monitoring can be performed by simulating the states of the battery cells in a computing unit in the form of a “digital twin”, in particular using a self-recognized battery performance model.

The electrochemical battery model includes a differential equation system that models internal battery conditions, in particular equilibrium conditions, based on differential equations parameterized via battery model parameters modeled using a time integration procedure and provides a state of charge of the battery cells of the device battery based on a relationship between operational variables of the battery cells of the device battery, i.e., a battery current, a battery voltage, and a battery temperature. Such an electrochemical battery models are known, for example, from the following publications: US 2016/023,566, US 2016/023,567 and US 2020/150,185. Model parameters of the battery performance model can be fitted with operational variable progressions of the battery cells within a limited time period (adjustment by least squares method), wherein electrochemical and kinetic parameters can be derived, e.g., electrolyte concentrations, reaction rates, layer thicknesses, porosities, etc. The ageing state of the respective battery cell can be determined as a linear combination of the model parameters and/or the internal states approximately.

The electrochemical battery performance model can be adjusted for each of the battery cells based on operational variables recorded in at rest phases within short periods of time (from several minutes to several hours). Based on the fitted electrochemical model parameters, the cell ageing state can be determined.

An age-dependent neutral voltage characteristic can be calculated analytically via a batch algorithm so that, by adjusting the idle voltage, the deduction of detailed electrochemical model parameters of the electrochemical battery model and thus the direct determination of the ageing state of the battery cells are directly possible.

The model parameters of the electrochemical battery performance model can be reparametrized at regular intervals, especially if there are sufficient new data on charging conditions and battery variables measured. These data can be collected for similar device batteries by evaluation in a central unit and adjustment or reparameterization can be performed there. Adjustment of the model parameters of the electrochemical battery performance model can be accomplished by fitting the battery performance model to the available data, e.g., using a least squares method or the like.

In particular, the monitoring serves to detect low-performing or vulnerable device batteries or battery cells and to detect faults early. The model parameters relating battery states in dynamic operation include, in particular, temperature dependent diffusion parameters in the anode and cathode of the battery cells, a thickness of the SEI, an electrolyte concentration, an ionic conductivity, a volume fraction of the electrolyte, a lithium ion concentration, an Ohmic resistance, and others.

It can be provided that the at least one predetermined model parameter is be adjusted depending on ageing, especially if a change in the ageing state by a predetermined change has occurred.

The model parameters of the electrochemical battery model can be reparametrized at regular intervals, in particular depending on ageing state of the battery cells or the device battery. The ageing state dependent model parameters are generally predetermined by the manufacturer, so that the ageing dependence of the model parameters can also be derived from or be predetermined by the manufacturer's predetermined model parameters.

The above method enables early detection of impending faults of battery cells or device batteries so that safety-critical situations can be avoided during use of the device battery. For this purpose, changes to model parameters of the electrochemical battery model are evaluated after an adjustment of the parameter setting so that slow changes in the battery behavior can be detected before they result in an actual failure or fault of the device battery or individual battery cells. First, deviations between the actual battery behavior or battery cell behavior and the behavior predicted by the electrochemical battery model are first detected based on the operational variable progressions, in particular by comparing the measured progression of the cell voltage or battery voltage and/or the measured and modeled progression of the battery temperature.

If one or more deviations within the progressions compared are above a predetermined threshold, then an anomaly is detected. Based on a detected anomaly, an adjustment of the model parameters is now made based on the most recently recorded operational variable progressions so that adjusted model parameters of the electrochemical battery model result. By comparing the adjusted model parameters with the model parameters specified by the manufacturer, which are corrected or adjusted depending on the ageing state, a fault can then be detected.

Fault detection is performed based on fault conditions that can be predetermined for a particular specific fault type according to one or more rules. For example, the deviations between the adjusted model parameters with the respective model parameters provided by the manufacturer can indicate the presence of a specific fault. If fault conditions for all rules associated with a fault type are satisfied, then the associated fault type is detected as the fault.

For example, an onset of thermal fault (as a possible fault mode) can be detected via model parameters indicative of dendrite formation or formation of a SEI layer. In particular, the deviations from specific adjusted model parameters can be aggregated from the corresponding predetermined model parameters, for example, by means of averaging, maximum formation, and the like, and so, using a threshold comparison, the presence of the specific fault mode can be detected.

The fault type and the amount of deviation detected between the adjusted model parameters and the predetermined model parameters can be indicative of the fault severity. Depending on the fault severity, continued operation of the device battery can be prevented and a user of the device battery or the battery-powered technical device can be informed accordingly.

Furthermore, the adjustment of the at least one model parameter of the electrochemical battery model can be performed based on the operational variable progression of the device battery or battery cell, which is recorded during a charging process of the device battery, in particular at constant charging current.

It can be provided that the adjustment of the at least one model parameter is performed if the provided operational variable progression deviates from an operational variable progression modeled using the battery model by more than one threshold amounting to at least one of the operational variables within the predetermined time period.

In particular, the operational variables of the operational variable progression can comprise a battery current, a battery voltage, a state of charge and a battery temperature, wherein adjustment of the at least one model parameter is performed if the progression of the provided battery voltage deviates at least once from a battery voltage modeled using the battery model within the predetermined time period by more than one voltage threshold and/or if the progression of the provided battery temperature deviates from a battery temperature modeled using the battery model by at least once by more than one predetermined temperature threshold within the predetermined time period.

According to a further aspect, a device is provided for performing one of the above methods.

### BRIEF DESCRIPTION OF THE DRAWINGS

Embodiments are described in further detail below with reference to the accompanying drawings. Shown are:

FIG. 1 a schematic illustration of a system for providing driver-specific and vehicle-specific operational variables for determining an ageing state of a vehicle battery in a central unit; and

FIG. 2 a flow chart illustrating a method for performing diagnostics of battery cells of a vehicle battery using model parameters of an electrochemical battery model.

### DETAILED DESCRIPTION

In the following, the method according to the invention is described with reference to vehicle batteries as device batteries in a variety of motor vehicles as similar devices. One or more electrochemical battery models are operated in the central unit and used to calculate and evaluate battery states. In the central unit, the ageing state models are continuously updated or retrained based on operational variables of the vehicle batteries in the vehicle fleet.

The example above is representative of a plurality of stationary or mobile devices with a network-independent energy supply, e.g., vehicles (electric vehicles, pedelecs, etc.), systems, machine tools, household appliances, IOT devices, and the like, which are connected via a corresponding communication connection (e.g., LAN, Internet) to an external central unit (cloud).

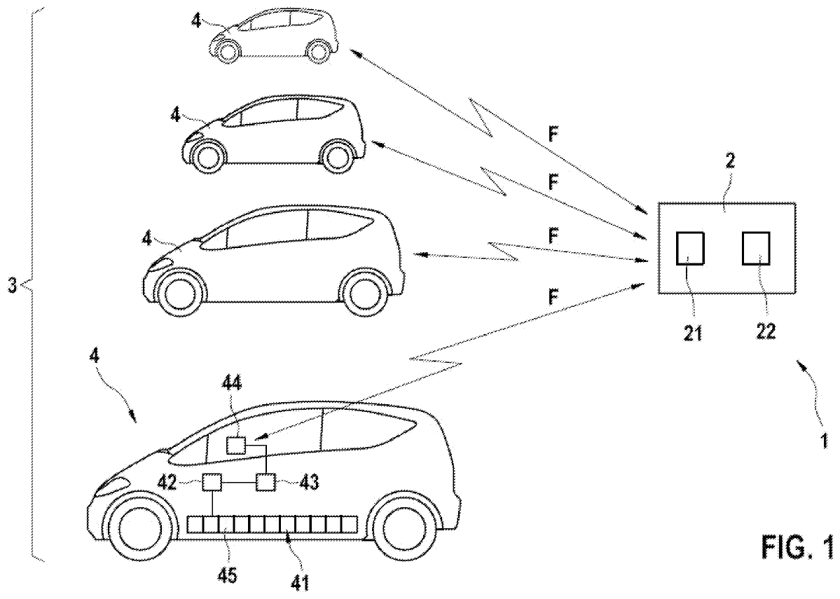

FIG. 1 shows a system 1 for collecting fleet data in a central unit 2 for creating, adjusting, and evaluating an electrochemical battery model for monitoring battery health. The electrochemical battery model is used to determine an internal battery state of battery cells, a pack of multiple battery cells, or the overall vehicle battery in a motor vehicle. FIG. 1 shows a vehicle fleet 3 with multiple motor vehicles 4.

One of the motor vehicles 4 is shown in more detail in FIG. 1. The motor vehicles 4 each comprise a vehicle battery 41, an electric drive motor 42, and a control unit 43. The control unit 43 is connected to a communication system 44, which is suitable for transmitting data between the respective motor vehicle 4 and a central unit 2 (a so-called cloud).

The vehicle battery 41 includes a plurality of battery cells 45 being monitored with regard to loading and ageing states according to methods described below.

The control unit 43 is in particular designed to provide data for selected, selectable, or all battery cells 45 having a high temporal resolution, e.g., between 1 and 50 Hz, e.g. 10 Hz, and transmits such to the central unit 2 via the communication device 44.

The motor vehicles 4 send the operational variables F to the central unit 2 indicating at least variables that affect the ageing state of the vehicle battery 41 and required for determining the internal states of the battery cells 45. In the case of a vehicle battery, the operational variables F can indicate an instantaneous battery current, an instantaneous battery voltage, an instantaneous battery temperature, and an instantaneous state of charge (SOC) at the pack, module, and/or cell level. The operational variables F are detected in a fast chronological grid from 0.1 Hz to 50 Hz and can be transmitted regularly to the central unit 2 in uncompressed and/or compressed form. For example, by using compression algorithms, the chronological series can be transmitted to the central unit 2 in blocks at intervals of 10 min to several hours in order to minimize data traffic to the central unit 2.

The central unit 2 comprises a data processing unit 21, in which the method described below can be performed, and a database 22 for storing data points, model parameters, states, and the like.

An electrochemical battery model is implemented in the central unit 2, which determines the instantaneous internal battery state of the vehicle battery 41 based on the temporal progression of the operational quantities and operational characteristics determined therefrom.

The central unit 2 is designed to receive the operational variable progressions and model a digital twin for each vehicle 4 or vehicle battery 41. In each battery cell 45, each pack of multiple battery cells or the entire vehicle battery 41, the digital twin determines a current battery state using the electrochemical battery model.

Furthermore, an appropriate ageing state model can be implemented in the central unit 2 that determines an ageing state depending on the internal state of the vehicle battery or by examining specific operating situations (e.g., during a charging process).

The ageing state (state of health, SOH) is the key variable for indicating a remaining battery capacity or remaining battery charge. The ageing state represents a measure of the ageing of the vehicle battery or of a battery module or of a battery cell and can be indicated as a capacity retention rate (SOH-C) or as an increase in internal resistance (SOH-R). The capacity retention rate SOH-C is indicated as the ratio between the measured instantaneous capacity and an initial capacity of the fully charged battery. The relative change in the internal resistance SOH-R increases with increasing ageing of the battery.

The electrochemical battery model is a non-linear mathematical model based on differential equations. Evaluation of the electrochemical battery model using operational variable progressions for a specific period of time is performed using a time integration method and results in a modeled internal battery state of the equation system of the physical differential equations corresponding to a physical internal battery state of the vehicle battery 41. Since the electrochemical battery model is based on physical and electrochemical principles, the model parameters of the physical ageing model are variables indicating physical properties.

The chronological series of the operational variables F for the vehicle battery 41 (in case of total battery evaluation) or the operational cell variables of the battery cells (in case of an individual assessment of the battery cells) are thus directly included in the electrochemical battery model, which preferably describes corresponding internal electrochemical states, such as layer thicknesses (e.g., SEI thickness), the change in cyclable lithium due to anode/cathode side reactions, rapid consumption of electrolytes, slow consumption of electrolytes, loss of active material in the anode, loss of active material in the cathode, etc., by means of non-linear differential equations and a multidimensional state vector.

The electrochemical battery model determines internal physical battery states dependent on the operational variables F, based on which an ageing state SOH can be determined. The internal battery state can be depicted linearly or nonlinearly with respect to a capacitance maintenance rate (SOH-C) and/or an internal resistance rate of increase (SOH-R) as an indication of the ageing state.

The electrochemical battery performance model can model equilibrium states and be described by model parameters. The model parameters can be reparametrized at regular intervals, particularly when operational variable progressions exist at a high sampling rate for a defined time period of at least several (e.g., three) hours. The electrochemical battery performance model can be adjusted according to the operational variable progressions during resting phases, e.g., using a least squares method or the like. This data can be collected for similar vehicle batteries 41 by evaluation in the central unit 2 and adjustment or reparameterization can be performed in the central unit.

Such model parameters can include, e.g., a scale indication of the cyclable lithium (“level” refers to the cathode capacity), the proportion of the cyclable lithium at the start of life of the battery (scale level), a volume fraction of the anode, and a volume fraction of the anode at the start of life of the device battery.

In order to recalibrate the electrochemical battery model, operational cell variable progressions are typically only necessary for a short period of time, e.g. several hours, in order to optimize model parameters describing the kinetics of the battery. In order to data the equilibrium model, the levels of the cell voltages and current flow rate between suitable idle phases of the battery are necessary.

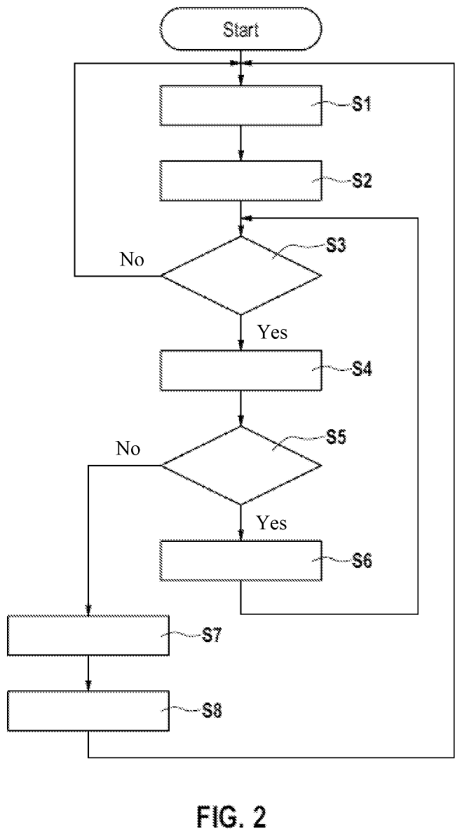

Adjustment of the model parameters of the electrochemical battery model is described in more detail using the flow diagram in FIG. 2 for the method performed in the central unit.

In step S1, operational variable progressions F are first transmitted from all vehicles 4 of the vehicle fleet 3 to the central unit 2 regarding operation of the vehicle batteries 41 included. The operational variable progressions correspond to temporal progressions of the operational variables of battery voltage, battery current, state of charge and battery temperature for a predetermined time period of, e.g., several hours.

In step S2, at predetermined evaluation times, e.g., after several hours, daily, or weekly for a predetermined period of time of, e.g., one to six hours, for each of the vehicle batteries or the battery cells, the relevant operational variable progression is checked to what extent the electrochemical battery model implemented in the central unit 2 properly maps the behavior of the relevant vehicle battery 41. For this purpose, the electrochemical battery model is evaluated using each of the operational variable progressions of the vehicle batteries or the battery cells. The evaluation is performed by, e.g., modeling based on a battery current progression, a battery temperature at the start of the predetermined period of the operational variable progression, a battery voltage at the start of the predetermined period of the operational variable progression of the state of charge, the battery voltage, and the battery temperature by means of a time integration method.

In step S3, during the period of time, the battery voltage progression modeled is compared to the measured battery voltage progression, which is also part of the operational variable progression received from the relevant vehicle. If a deviation of the modeled battery voltage from the measured battery voltage is detected for more than a predetermined voltage threshold (alternative: Yes) at one point in time, then an anomaly is determined and the method proceeds to step S4. Otherwise (alternative: No), a jump back to step S1 occurs.

Alternatively or additionally, in step S3, a history of the battery temperature can be modeled based on the battery temperature at the start of the predetermined period of time and compared to the history of the battery temperature measured. A deviation beyond a predetermined temperature threshold, which can be predetermined absolute or relative, can also be detected as an anomaly.

In step S4, the ageing state of the device battery 41 or battery cells is then determined using a suitable ageing state model.

To this end, it is in step S5 checked whether the ageing state determined deviates with respect to an ageing state and a detected ageing state occurring during a recent anomaly deviating by more than a predetermined threshold amount, e.g., by more than 2%. If this is the case (alternative: Yes), then in step S6 the predetermined model parameters of the underlying electrochemical battery model are adjusted according to the changed ageing, in particular in a manner that can also be specified by the manufacturer. As a result, a model parameter set, which can be predetermined by the manufacturer, is available for each ageing state. Alternatively, the set of model parameters for the electrochemical battery model can also be determined by means of a suitable computing regimen, e.g., a multiplication/division of the original model parameters by the amount of the ageing state.

The method then continues in step S3.

If no (substantial) deviation of the ageing state is detected in step S5 since the last anomaly detection (alternative: No), then the model parameters are adjusted in step S7 based on the most recently recorded operational variable progressions. A set of model parameters can be compared with predetermined model parameters adjusted for the ageing state for the device battery or when monitoring at the cell level of each of the battery cells of the device battery.

Rules are provided that evaluate a deviation between one or more of the adjusted model parameters and one or more of the predetermined model parameters dependent on the ageing state for each of the battery cells for the device battery or when monitoring at the cell level, respectively. The rules can be created based on domain knowledge and can specify criteria denoting a specific fault type and specific fault severity. Based on the predetermined rules, which can each indicate a fault type and fault severity, a fault type can be detected in step S8 and, optionally, a fault severity can be signaled according to the fault severity. The method is performed cyclically.

For example, an impending fault (as a possible fault type) can be detected by means of model parameters correlated to disproportionately high dendrite formation or the formation of an SEI layer. In particular, deviation thresholds can be provided for the model parameters, which can indicate a fault severity. Alternatively, in addition to the deviation, in particular using a threshold comparison of a model parameter gradient can in particular be evaluated, by means of which it is indicated how quickly the model parameter in question, and thus the behavior of the vehicle battery or battery cell in question, is changing.

The method described can be performed in particular for operational variable progressions during charging operation. A charging operation represents a stationary operation of a device battery, so that the above method provides robust results in anomaly detection. Depending on the fault type and fault severity predetermined by way of deviation levels or gradient levels, corresponding signaling can be made to the driver of the motor vehicle or, optionally, the function of the vehicle battery can be restricted or blocked in order to avoid endangering the vehicle and the driver.

1. A method for detecting a fault of a device battery (41) or battery cell (45) in a technical device (4) using an electrochemical battery model, wherein the battery model is based on a differential equation system and designed to indicate a progression of at least one operational variable dependent on an internal battery state determined by at least one model parameter of the battery model, said method comprising the following steps:
providing (S1) a temporal operational variable progression of multiple operational variables for a period of time;
adjusting (S7) the at least one model parameter of the electrochemical battery model based on the operational variable progression over the period of time;
detecting (S8) a fault type dependent on at least one predetermined rule, wherein the at least one rule indicates a fault condition dependent on at least one deviation of the at least one model parameter from a corresponding predetermined model parameter; and
when the fault condition of the at least one rule is satisfied, signaling (S8) the fault type.

2. The method according to claim 1, wherein the at least one predetermined model parameter is adjusted according to ageing if a change in the ageing state has occurred by a predetermined change amount.

3. The method according to claim 1, wherein the adjustment of the at least one model parameter of the electrochemical battery model is performed based on the operational variable progression of the device battery (41) or battery cell (45), which progression is recorded during a charging operation of the device battery (41) at a constant charging current.

4. The method according to claim 1, wherein the method is performed in a central unit (2) external to the device and communicatively connected to a plurality of device batteries and providing the electrochemical battery model for for all battery cells (45) of the device batteries (41), wherein operational variable progressions of all device batteries (41) and the battery cells (45) are provided in the central unit (2), and adjustment of the at least one model parameter based on the operational variable progressions is performed in the central unit (2).

5. The method according to claim 1, wherein adjustment of the at least one model parameter is performed when the provided operational variable progression deviates from an operational variable progression modeled using the battery model by at least one of the operational variables in an amount by more than one threshold level within the predetermined time period.

6. The method according to claim 5, wherein the operational variables of the operational variable progression comprise a battery current, a battery voltage, a state of charge, and a battery temperature, wherein adjustment of the at least one model parameter is performed if the battery voltage progression provided deviates at least once from a battery voltage modeled using the battery model within the predetermined time period by more than one voltage threshold and/or if the battery temperature progress provided deviates from a battery temperature modeled using the battery model by at least once by more than one predetermined temperature threshold within the predetermined time period.

7. An apparatus comprising a data processing device configured to:
provide (S1) a temporal operational variable progression of multiple operational variables for a period of time;
adjust (S7) at least one model parameter of an electrochemical battery model based on the operational variable progression over the period of time, wherein the electrochemical battery model is based on a differential equation system and designed to indicate a progression of at least one operational variable dependent on an internal battery state determined by at least one model parameter of the battery model;
detect (S8) a fault type dependent on at least one predetermined rule, wherein the at least one rule indicates a fault condition dependent on at least one deviation of the at least one model parameter from a corresponding predetermined model parameter; and
when the fault condition of the at least one rule is satisfied, signal (S8) the fault type.

8. (canceled)

9. A non-transitory computer-readable medium including instructions executable by a data processing device to perform a set of functions, the set of functions comprising:
providing (S1) a temporal operational variable progression of multiple operational variables for a period of time;
adjusting (S7) at least one model parameter of an electrochemical battery model based on the operational variable progression over the period of time, wherein the electrochemical battery model is based on a differential equation system and designed to indicate a progression of at least one operational variable dependent on an internal battery state determined by at least one model parameter of the battery model;
detecting (S8) a fault type dependent on at least one predetermined rule, wherein the at least one rule indicates a fault condition dependent on at least one deviation of the at least one model parameter from a corresponding predetermined model parameter; and
when the fault condition of the at least one rule is satisfied, signaling (S8) the fault type.
